(19) United States
(12) Patent Application Publication
(10) Pub. No.: US 2026/0036907 A1
(43) Pub. Date: Feb. 5, 2026

(54) FILM FORMING APPARATUS, ALIGNMENT METHOD, STORAGE MEDIUM, AND MANUFACTURING METHOD FOR ARTICLE

(71) Applicant: CANON KABUSHIKI KAISHA, Tokyo (JP)

(72) Inventor: NOZOMU HAYASHI, Tochigi (JP)

(21) Appl. No.: 19/273,927

(22) Filed: Jul. 18, 2025

(30) Foreign Application Priority Data
Aug. 1, 2024 (JP) 2024-125742

(51) Int. Cl. G03F 7/16; G01B 11/02; G01B 11/08

(52) U.S. Cl. CPC G03F 7/16; G01B 11/028; G01B 11/08

(57) ABSTRACT

A film forming apparatus that brings a curable composition on a substrate and a member into contact with each other to form a film of the curable composition includes a first unit including a first detection unit configured to detect an edge of the substrate, a second unit including a second detection unit configured to detect an edge of the substrate and a driving unit configured to drive at least one of the substrate and the second detection unit, a conveyance unit configured to convey the substrate from the first unit to the second unit; and a control unit configured to control the driving unit, wherein the control unit controls the driving unit based on information about a position of the edge of the substrate acquired from a detection result of the first detection unit.

### BACKGROUND

### Field of the Technology

The present disclosure relates to a film forming apparatus, an alignment method, a storage medium, and a manufacturing method for an article.

### Description of the Related Art

In manufacturing processes for semiconductor devices, liquid crystal display devices, and the like, a film forming apparatus that forms a film of a curable composition on a substrate is sometimes used. According to Japanese Patent Application Laid-Open No. 2017-55115, a technique is discussed in which supply of an imprint material to a shot region arranged on a periphery of a substrate is controlled based on a relative position of the shot region arranged on the periphery of the substrate and an edge of the substrate.

Here, if a position of the edge of the substrate varies, it may take a long time to arrange the edge of the substrate within a detectable region of a detection unit, resulting in a decrease in throughput.

### SUMMARY

Therefore, the present disclosure is directed to the provision of a film forming apparatus that is advantageous in terms of throughput.

According to an aspect of the present invention, a film forming apparatus that brings a curable composition on a substrate and a member into contact with each other to form a film of the curable composition includes a first unit including a first detection unit configured to detect an edge of the substrate, a second unit including a second detection unit configured to detect an edge of the substrate and a driving unit configured to drive at least one of the substrate and the second detection unit, a conveyance unit configured to convey the substrate from the first unit to the second unit; and a control unit configured to control the driving unit, wherein the control unit controls the driving unit based on information about a position of the edge of the substrate acquired from a detection result of the first detection unit.

Features of the present disclosure will become apparent from the following description of embodiments with reference to the attached drawings. The following description of embodiments is described by way of example.

### BRIEF DESCRIPTION OF THE DRAWINGS

FIG. 1 is an outline drawing of a film forming apparatus.

FIG. 2 is a schematic diagram of a pre-alignment unit.

FIG. 3 is a schematic diagram of an application unit.

FIG. 4 is a schematic diagram of a forming unit.

FIG. 5 is a flowchart illustrating processing from pre-alignment processing to forming processing according to one or more aspects of the present disclosure.

FIG. 6 is a flowchart illustrating a method for manufacturing an article according to one or more aspects of the present disclosure.

### DESCRIPTION OF THE EMBODIMENTS

Exemplary embodiments of the present disclosure will be described below with reference to the attached drawings. The exemplary embodiments which will be described below do not restrict the present disclosure according to the claims. A plurality of features is described in the exemplary embodiments, but not all of these features are essential to the present disclosure, and the exemplary embodiments may be arbitrarily combined. Further, the same or similar components in the attached drawings are denoted by the same reference numerals, and redundant description will be omitted.

In the present specification and drawings, directions are basically indicated by an XYZ coordinate system in which the vertical direction is a Z-axis direction, a horizontal plane perpendicular to the vertical direction is an XY plane, and each axis is orthogonal to each other. However, if the XYZ coordinate system is illustrated in each drawing, the illustrated XYZ coordinate system is given priority.

A specific configuration will be described below for each exemplary embodiment.

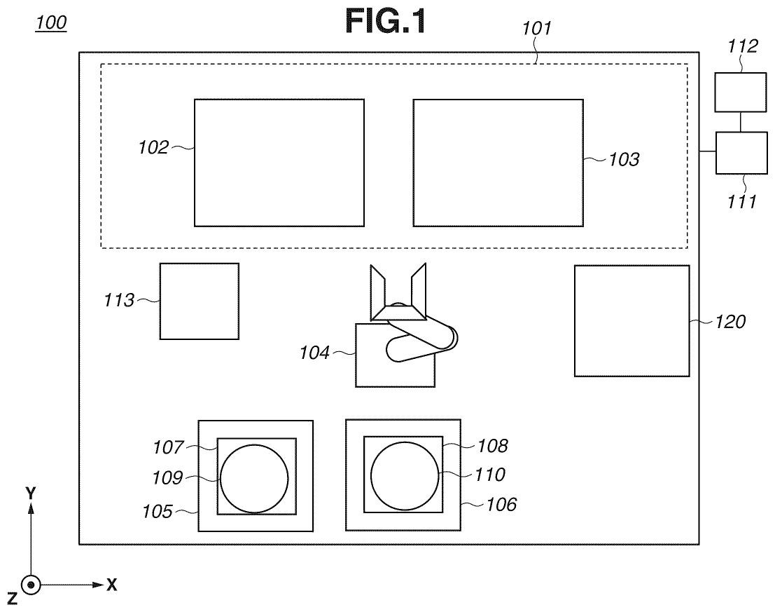

A first exemplary embodiment is described. FIG. 1 is an outline drawing of a film forming apparatus 100. The film forming apparatus 100 includes a member carrying-in/out mechanism 105, a substrate carrying-in and carrying-out mechanism 106, a conveyance unit 104, a pre-alignment unit (first unit) 113, a processing unit (second unit) 101, a heat treatment unit 120, a control unit 111, and a storage unit 112. The film forming apparatus 100 is an apparatus that brings a member 109 into contact with a curable composition 201 applied on a substrate 110 and cures the curable composition 201, thereby forming a film of the curable composition 201 on the substrate 110.

The member 109 is transparent to ultraviolet light and includes, for example, quartz, glass, polymethyl methacrylate (PMMA), and a polycarbonate resin. The film forming apparatus 100 according to the present exemplary embodiment is a flattening apparatus that forms a flat film of the curable composition 201 on the substrate 110. Further, the member 109 has a flat surface on which the curable composition 201 can be flattened. However, the film forming apparatus 100 may be an imprint apparatus that forms a pattern on the curable composition 201 on the substrate 110. In a case where the film forming apparatus 100 is an imprint apparatus, the member 109 is a member on which a depression-protrusion pattern to be transferred to the curable composition 201 on the substrate 110 is formed.

The substrate 110 includes, for example, silicon and glass. The substrate 110 may include an adhesion layer formed on its surface. The substrate 110 has a circular outer peripheral shape with a diameter of, for example, 300 mm or 200 mm and is formed with a notch, which is a V-shaped notch portion, or an orientation flat, which is a linear notch portion.

The curable composition 201 is a composition (for example, a resin) that is cured by ultraviolet light or heat. The curable composition 201 may contain any of a polymerizable compound, a photopolymerization initiator, a non-polymerizable compound, and a solvent and may contain at least any of a sensitizer, a hydrogen donor, an internal additive separation material, a surfactant, an antioxidant, and a polymer component as a non-polymerizable compound.

The member 109 to be used is carried in to the member carrying-in and carrying-out mechanism 105, and the member 109 already used is carried out therefrom. Further, the substrate 110 to be processed is carried in to the substrate carrying-in and carrying-out mechanism 106, and the substrate 110 already processed is carried out therefrom. Carrying in and out is not limited to one each, and for example, a carrier that stores a plurality of members 109 or substrates 110 may be carried in and out. In the example in FIG. 1, the member 109 is stored in a member carrier 107, and the substrate 110 is stored in a substrate carrier 108. The conveyance unit 104 is a mechanism that conveys the member 109 or the substrate 110 to each unit and includes, for example, a hand for conveying the member 109 or the substrate 110.

The pre-alignment unit 113 measures the conveyed substrate 110 and aligns the substrate 110 at a predetermined rotation angle. The pre-alignment unit 113 adjusts the substrate 110 to the predetermined rotation angle, so that the substrate 110 can be conveyed to an application unit 102 and a forming unit 103 at the predetermined rotation angle. The rotation angle of the substrate 110 is a rotation angle about an axis (Z-axis) orthogonal to a surface (XY plane) of the substrate 110. The pre-alignment unit 113 is described in detail below.

The processing unit 101 includes the application unit 102 and the forming unit 103. The application unit 102 applies the curable composition 201 onto the substrate 110. The forming unit 103 brings the curable composition 201 applied by the application unit 102 into contact with the member 109, cures the curable composition 201, and thus forms a film of the curable composition 201 on the substrate 110. The application unit 102 and the forming unit 103 are described in detail below.

The heat treatment unit 120 heats the substrate 110 processed in the processing unit 101 to further cure the curable composition 201 on the substrate 110. In a case where the curable composition 201 can be sufficiently cured solely in the forming unit 103, the film forming apparatus 100 does not need to be provided with the heat treatment unit 120.

The control unit 111 controls each unit in the film forming apparatus 100. The control unit 111 includes an information processing unit, a bus, a read-only memory (ROM), a random access memory (RAM), and a storage device, and each component functions according to a program. The information processing unit is a processing device that performs calculation for control according to a program and controls each component connected to the bus. The information processing unit can be configured with a central processing unit (CPU), a programmable logic device (PLD) such as a field programmable gate array (FPGA), an application specific integrated circuit (ASIC), a computer with an embedded program, or a combination of all or a part of these components. The ROM is a memory dedicated to reading data and stores a program and data. The RAM is a memory for reading and writing data and is used to store a program and data. The RAM is used to temporarily store data such as a calculation result of the CPU. The storage device is also used to store a program and data. The storage device is also used as a temporary storage area for data and a program of an operating system (OS) of the control unit 111. The storage device is slower to input and output data than the RAM but can store a large amount of data. The storage device is desirably a non-volatile storage device that can store data as permanent data so that the stored data can be referred to for a long period of time. The storage device mainly includes a magnetic storage device (hard disk drive (HDD)), but may also be a device that reads and writes data by loading an external medium such as a compact disk (CD), a digital versatile disk (DVD), and a memory card. The control unit 111 may be provided integrally with other units in the film forming apparatus 100 (in a common housing) or may be provided externally to the film forming apparatus 100. The storage unit 112 may be arranged within the control unit 111.

According to the present exemplary embodiment, an example is described in which the film forming apparatus 100 includes one of each of the units but may include a plurality of each of the units. For example, the film forming apparatus 100 may include two each of the pre-alignment units 113, the application units 102, and the forming units 103.

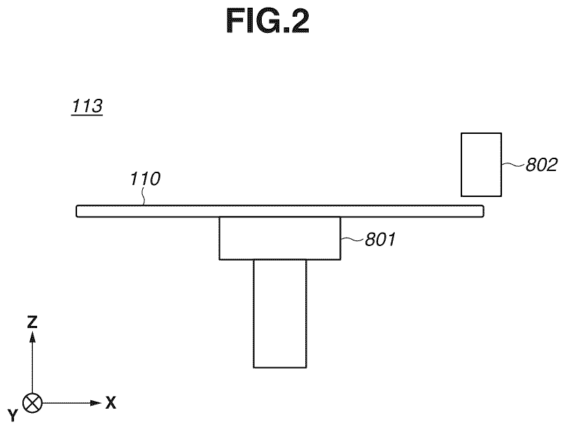

FIG. 2 is a schematic diagram of the pre-alignment unit 113. The pre-alignment unit 113 includes a rotation unit 801 and a first detection unit 802. The rotation unit 801 holds and rotates the substrate 110. The first detection unit 802 detects a position of an orientation flat or a notch of the rotating substrate 110. Detection by the first detection unit 802 is continuously performed, for example, on the rotating substrate 110. In other words, the detection by the first detection unit 802 is performed, for example, at a plurality of points on an edge of the rotating substrate 110. The control unit 111 rotates and adjusts the rotation unit 801 so that the substrate 110 is placed at the predetermined rotation angle based on the detected position of the orientation flat or the notch. According to the present exemplary embodiment, the control unit 111 calculates the diameter (diameter or radius) of the substrate 110 based on a result of the detection of the edge of the substrate 110 by the first detection unit 802. The diameter of the substrate 110 can be calculated by measuring three or more positions on the substrate 110 that are not the orientation flat and the notch (positions other than the notch portion). The first detection unit 802 is, for example, a line sensor.

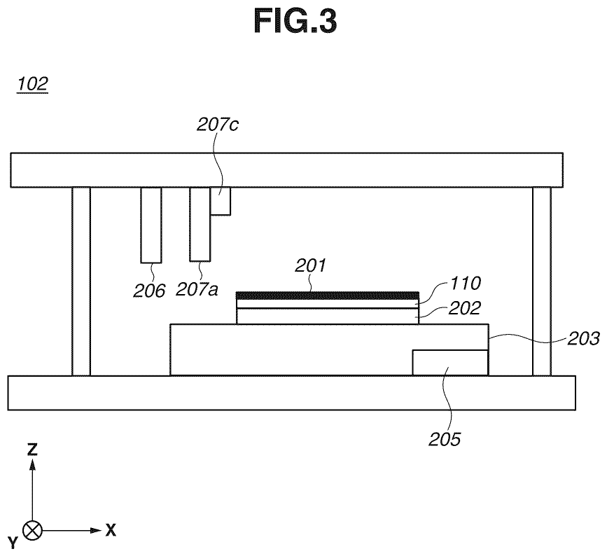

FIG. 3 is a schematic diagram of the application unit 102. The application unit 102 includes a substrate chuck 202, a substrate stage 203, a dispenser 206, a second detection unit 207a, and a detection unit driving unit 207c that drives the second detection unit 207a. The substrate stage 203 includes a substrate driving unit 205 and moves, in a state where the substrate chuck 202 holding the substrate 110 is placed thereon, so that the substrate 110 is placed at an arbitrary position (position on six axes: X-axis, Y-axis, Z-axis, rotation axis about the X-axis, rotation axis about the Y-axis, and rotation axis about the Z-axis). The substrate chuck 202 holds the substrate 110 using, for example, a vacuum suction method or an electrostatic adsorption method. The substrate driving unit 205 is, for example, a linear motor. The dispenser 206 supplies, places, or applies the curable composition 201 to the substrate 110 that is moved to an arbitrary position. The dispenser 206 includes a nozzle for ejecting a droplet of the curable composition 201 onto the substrate 110. An ejection method can be a piezo jet method or a micro solenoid method. The number of nozzles included in the dispenser 206 is not particularly limited, and the nozzles may be arranged in a nozzle array with a single row or a nozzle array with a plurality of rows.

The second detection unit 207a is, for example, an off-axis scope and detects a reference mark arranged on the substrate stage 203 and a mark formed on the substrate 110 held by the substrate chuck 202. The control unit 111 adjusts the position of the substrate 110 using a relative position of the reference mark arranged on the substrate stage 203 and the mark formed on the substrate 110. Accordingly, a relative position of the dispenser 206 and the substrate 110 can be set to a desired relative position, and the curable composition 201 can be applied to a desired position on the substrate 110.

An off-axis scope can include a light source, an imaging clement, and an optical system that directs light for detection to an object to be inspected or the imaging element. According to the present exemplary embodiment, an example is described in which the substrate stage 203 includes the substrate driving unit 205 and moves, but the dispenser 206 may include a driving unit and move.

The second detection unit 207a detects the edge of the substrate 110. The second detection unit 207a detects the edge of the substrate 110, so that a center position of an outer shape reference (outer diameter reference) of the substrate 110 can be calculated. Accordingly, a difference (deviation amount) between a center position of a mark reference formed on the substrate 110 and the center position of the outer shape reference of the substrate 110 can be acquired, and the relative position of the dispenser 206 and the substrate 110 can be set to a further desired relative position. In other words, the difference is a misalignment amount between the outer shape of the substrate and the mark. In a case where the second detection unit 207a is a detection unit such as an off-axis scope that includes an imaging element, the position of the edge of the substrate 110 is detected based on a captured image.

In a case where a droplet of the curable composition 201 is applied near the edge of the substrate 110, the curable composition 201 may seep out into an area other than a space between the member 109 and the substrate 110 when the member 109 and the substrate 110 are brought into contact with each other. Thus, it is desirable to detect the position of the edge of the substrate 110 by the second detection unit 207a and apply the curable composition 201 to a position away from the position of the edge. In other words, it is desirable to adjust a supply position of the droplet of the curable composition 201 according to the position of the edge of the substrate 110. Further, a supply amount of the curable composition 201 to a shot region arranged on a periphery of the substrate 110 may be less than a supply amount of the curable composition 201 to the shot region arranged in the center of the substrate 110. Accordingly, the curable composition 201 can be suppressed from seeping out. The diameter of the substrate 110 varies due to a tolerance of the substrate 110 and shrinkage caused by etching, heating, and the like in the process of processing the substrate 110. Thus, the second detection unit 207a detects the edge of each substrate 110, and accordingly the curable composition 201 can be appropriately applied.

The second detection unit 207a detects the edge of the substrate 110 at a position avoiding the notch and the orientation flat of the substrate 110. In a case where the second detection unit 207a is a detection unit that detects an object by capturing an image thereof such as an off-axis scope, the control unit 111 identifies the edge of the substrate 110 by a contrast of the image captured by the second detection unit 207a. The second detection unit 207a may be a length measurement sensor that measures a distance by irradiating a periphery of the edge of the substrate 110 with light from above the substrate 110. In a case where the second detection unit 207a is the length measurement sensor, the control unit 111 identifies a portion having a height difference of a certain level or more (a portion having a step) as the edge of the substrate 110.

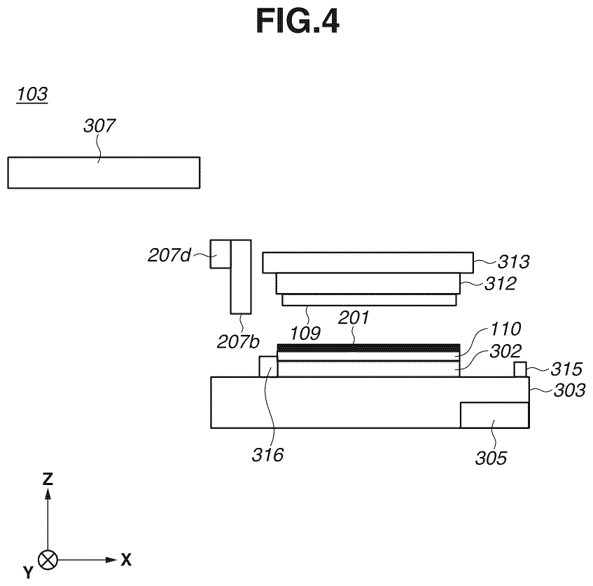

FIG. 4 is a schematic diagram of the forming unit 103. The forming unit 103 includes a substrate chuck 302, a substrate stage 303, an illumination unit 307, a member chuck 312, a head 313, an upward sensor 315, a separation assist mechanism 316, a second detection unit 207b, and a detection unit driving unit 207d. The substrate stage 303 includes a substrate driving unit 305 and moves, in a state where the substrate chuck 302 holding the substrate 110 is placed thereon, so that the substrate 110 is placed at an arbitrary position (position on six axes: X-axis, Y-axis, Z-axis, rotation axis about the X-axis, rotation axis about the Y-axis, and rotation axis about the Z-axis). The substrate chuck 302 holds the substrate 110 using, for example, a vacuum suction method or an electrostatic adsorption method. The substrate driving unit 305 is, for example, a linear motor.

The member chuck 312 is a holding unit that holds the member 109. The member chuck 312 holds the member 109 using, for example, a vacuum suction method or an electrostatic adsorption method. The head 313 holds the member chuck 312. The head 313 includes a driving unit (not illustrated) and moves the member chuck 312 (the member 109) in a direction parallel to the Z-axis direction.

The upward sensor 315 detects (measures) the position of the member 109. Based on a detection result of the position of the member 109 by the upward sensor 315, the member 109 and the substrate 110 are aligned. The upward sensor 315 is, for example, a displacement sensor using an interference method or a gap sensor that can measure a distance. Alternatively, the upward sensor 315 may be a sensor that captures an image of a specific position of the member 109 to identify the position of the member 109.

The second detection unit 207b is, for example, an off-axis scope and detects the reference mark arranged on the substrate stage 303 and the mark formed on the substrate 110 held by the substrate chuck 302. Then, the control unit 111 adjusts the position of the substrate 110 using the relative position of the reference mark arranged on the substrate stage 303 and the mark formed on the substrate 110. Accordingly, the relative position of the member 109 and the substrate 110 can be set to the desired relative position. An off-axis scope can include a light source, an imaging element, and an optical system that directs light for detection to an object to be inspected or the imaging element.

Further, the second detection unit 207b detects the edge of the substrate 110. The second detection unit 207b detects the edge of the substrate 110, so that the center position of the outer shape reference of the substrate 110 can be calculated. Accordingly, the difference (deviation amount) between the center position of the mark reference formed on the substrate 110 and the center position of the outer shape reference of the substrate 110 can be acquired, and the relative position of the member 109 and the substrate 110 can be set to a further desired relative position. In a case where the second detection unit 207b is a detection unit such as an off-axis scope that includes an imaging element, the position of the edge of the substrate 110 is detected based on a captured image.

The second detection unit 207b detects the edge of the substrate 110 at a position avoiding the notch and the orientation flat of the substrate 110. In a case where the second detection unit 207b is a detection unit that detects an object by capturing an image thereof such as an off-axis scope, the control unit 111 identifies the edge of the substrate 110 by a contrast of the image captured by the second detection unit 207b. The second detection unit 207b may be a length measurement sensor, and in a case where the second detection unit 207b is the length measurement sensor, the control unit 111 identifies a portion having a height difference of a certain level or more (a portion having a step) as the edge of the substrate 110.

The separation assist mechanism 316 is a mechanism for separating the member 109 from the curable composition 201 that has been illuminated with light by the illumination unit 307 and cured. The separation assist mechanism 316 includes, for example, a pin that can be driven in the Z-axis direction and assists separation in such a manner that the pin passes through the notch portion of the substrate 110 such as the notch or the orientation flat and comes into contact with the member 109 to push up the member 109.

Forming processing in the forming unit 103 is described. First, the second detection unit 207b detects the position of the edge of the substrate 110. Next, the upward sensor 315 detects the position of the member 109. The control unit 111 drives the substrate stage 303 to align the member 109 and the substrate 110 based on a detection result (the position of the substrate 110) of the second detection unit 207b and a detection result (the position of the member 109) of the upward sensor 315. Next, the head 313 is driven to bring the member 109 into contact with the curable composition 201 on the substrate 110 held by the substrate chuck 302. Next, the member chuck 312 releases the holding of the member 109. Accordingly, the member 109 is in a state of being placed on the curable composition 201. In this state, the substrate stage 303 is moved below the illumination unit 307. Then, the curable composition 201 is cured by the light emitted from the illumination unit 307. In other words, the curable composition 201 is cured in a state in which a shape of a contact surface of the member 109 is transferred thereto. In a case where the contact surface of the member 109 with the curable composition 201 is flat, a surface of the curable composition 201 is formed flat. In a case where a depression-protrusion pattern is formed on the contact surface of the member 109 with the curable composition 201, an inverted depression-protrusion pattern of the member 109 is formed on the surface of the curable composition 201.

Next, the substrate stage 303 is moved below the member chuck 312, and the head 313 is driven to bring the member 109 and the member chuck 312 into contact with each other. Next, the member chuck 312 holds the member 109. Then, the head 313 is driven to separate the member 109 held by the member chuck 312 and the curable composition 201 cured on the substrate 110. At this time, the separation assist mechanism 316 may assist the separation.

According to the present exemplary embodiment, an example is described in which the member 109 and the substrate 110 are aligned by driving the substrate stage 303 and the member 109 and the curable composition 201 are brought into contact with each other by driving the head 313, but the present disclosure is not limited to this example. In the alignment, it is sufficient that the relative position of the member 109 and the substrate 110 is adjusted, and for example, the head 313 may be driven for alignment. Further, in the contact, it is sufficient that the relative position of the member 109 and the substrate 110 is changed for contact, and for example, the substrate stage 303 may be driven for contact.

In a case where the film forming apparatus 100 is an imprint apparatus, the cured curable composition 201 and the member 109 are in contact with each other not over the entire substrate 110 but only in the shot region, so that the curable composition 201 and the member 109 can be separated from each other without the separation assist mechanism 316. Thus, in this case, the separation assist mechanism 316 may not be required. Further, in a case where the film forming apparatus 100 is an imprint apparatus, a method for detecting the relative position of the marks formed respectively on the member 109 and the substrate 110 may be used without using the upward sensor 315 to align the member 109 and the substrate 110. In this case, the imprint apparatus includes an optical system that detects the relative position of the marks formed respectively on the member 109 and the substrate 110. In addition, the imprint apparatus may further include a mechanism for changing a shape of the member 109, an optical system for correcting the shape of the substrate 110 by irradiating it with light, and an optical system for partially curing the curable composition 201 by irradiating it with light. Furthermore, in a case where the film forming apparatus 100 is the imprint apparatus, processing may be performed without releasing the member 109 held by the member chuck 312 in a series of processes. According to the present exemplary embodiment, an example is described in which a position of the head 313 and a position of the illumination unit 307 are different in a direction orthogonal to the Z-axis direction, but the position of the head 313 and the position of the illumination unit 307 may overlap in the direction orthogonal to the Z-axis direction. In other words, after the member 109 and the curable composition 201 are brought into contact with each other, the substrate stage 303 may not be moved, and the illumination unit 307 may irradiate the substrate 110 with light at the position where the member 109 and the curable composition 201 are brought into contact with each other.

Here, as described above, the position of the edge of the substrate 110 may vary due to the tolerance of the substrate 110 and shrinkage of the substrate 110 caused by etching, heating, and the like in the process of processing the substrate 110. Specifically, the diameter of the substrate 110 may vary due to the tolerance of the substrate 110 and the shrinkage of the substrate 110 caused by etching, heating, and the like in the process of processing the substrate 110. When the second detection unit 207 (including the second detection unit 207a and the second detection unit 207b) detects the edge of the substrate 110 in a case where the position of the edge of the substrate 110 varies, it may take time to bring the edge of the substrate 110 into a detectable region. Conventionally, the second detection unit 207 needs to detect three or more points on the edge of the substrate 110 in order to measure the diameter and the position of the substrate 110. However, due to the variation in the position of the edge of the substrate 110, it takes a long time for the second detection unit 207 to detect three or more points on the edge of the substrate 110.

Thus, according to the present exemplary embodiment, the second detection unit 207 performs detection based on information about the position of the edge of the substrate 110 acquired from a detection result of the edge of the substrate 110 by the pre-alignment unit 113. Accordingly, it is possible to shorten a time required to bring the edge of the substrate 110 within the detectable region of the second detection unit 207 and also to reduce the number of times the second detection unit 207 detects the substrate 110.

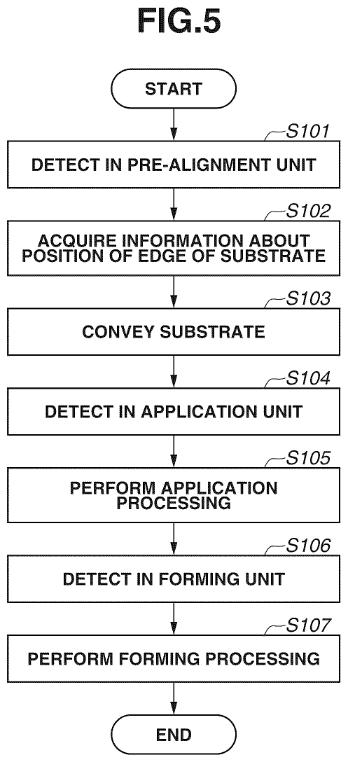

FIG. 5 is a flowchart illustrating processing from pre-alignment processing to forming processing according to the present exemplary embodiment. First, in step S101, in the pre-alignment unit 113, the first detection unit 802 detects an index for specifying the rotation angle of the substrate 110 such as the orientation flat or the notch of the substrate 110 and also detects three or more points on the edge of the substrate 110 at positions that are not the orientation flat or the notch (first detection process). Next, in step S102, information about the position of the edge of the substrate 110 is acquired (calculated) based on the detection result of the edge (the position of the edge) of the substrate 110 in the pre-alignment unit 113 (acquisition process). The information about the position of the edge of the substrate 110 includes, for example, at least one of information about the diameter (outer diameter) of the substrate 110 and information about the radius of the substrate 110. The diameter of the substrate 110 may be calculated by the control unit 111 or the first detection unit 802.

Next, in step S103, the substrate 110 the rotation angle (direction) of which is adjusted based on the measurement result by the pre-alignment unit 113 is conveyed by the conveyance unit 104 to the application unit 102 (conveyance process). In step S104, the second detection unit 207a detects the edge of the substrate 110 in the application unit 102 (second detection process). In the detection by the second detection unit 207a in the application unit 102, the control unit 111 drives at least one of the substrate driving unit 205 or the detection unit driving unit 207c to adjust the relative position of the substrate 110 and the second detection unit 207a based on the acquired information about the position of the edge of the substrate 110. In other words, the control unit 111 controls at least one of the substrate driving unit 205 or the detection unit driving unit 207c based on the information about the position of the edge of the substrate 110 acquired from the detection result of the first detection unit 802.

Accordingly, the edge of the substrate 110 can be easily brought into the detectable region of the second detection unit 207a, and it is possible to reduce the time required to bring the edge of the substrate 110 into the detectable region of the second detection unit 207a. Further, since the diameter of the substrate 110 is already known, the second detection unit 207a does not need to detect three or more points on the substrate 110 but only needs to detect at least two points (two or more points). This is because, if there are the already known diameter of the substrate 110 and detection results of at least two points on the edge of the substrate 110, the position of the substrate 110 and the center position of the outer shape reference of the substrate 110 can be calculated. In step S104, the second detection unit 207a also detects the mark formed on the substrate 110.

Next, in step S105, the application unit 102 performs application processing for applying the curable composition 201 from the dispenser 206 onto the substrate 110. In the application processing, the control unit 111 aligns the dispenser 206 and the substrate 110 based on the relative position of the reference mark arranged on the substrate stage 203 and the mark formed on the substrate 110. In the alignment, the difference (deviation amount) between the center position of the outer shape reference of the substrate 110 acquired from the detection result of the edge of the substrate 110 by the second detection unit 207a and the center position of the mark reference formed on the substrate 110 is also reflected. Further, in order to suppress the curable composition 201 from seeping out as described above, the supply position of the curable composition 201 to the edge of the substrate 110 may be adjusted based on the detection result of the edge of the substrate 110 by the second detection unit 207a. Alternatively, the supply amount of the curable composition 201 to the shot region on the periphery of the substrate 110 (the shot region near the edge of the substrate 110) may be adjusted based on the detection result of the edge of the substrate 110 by the second detection unit 207a. Further, in order to suppress the curable composition 201 from seeping out, the supply position of the curable composition 201 to the edge of the substrate 110 may be adjusted based on not the detection result by the second detection unit 207a but the detection result of the edge of the substrate 110 by the first detection unit 802. Alternatively, the supply amount of the curable composition 201 to the shot region on the periphery of the substrate 110 (the shot region near the edge of the substrate 110) may be adjusted based on the detection result of the edge of the substrate 110 by the first detection unit 802.

Next, in step S106, the substrate 110 is conveyed by the conveyance unit 104 to the forming unit 103, and the second detection unit 207b detects the edge of the substrate 110 in the forming unit 103 (second detection process). In the detection by the second detection unit 207b in the forming unit 103, the control unit 111 drives at least one of the substrate driving unit 305 or the detection unit driving unit 207d to adjust the relative position of the substrate 110 and the second detection unit 207b based on the acquired information about the position of the edge of the substrate 110. In other words, the control unit 111 controls at least one of the substrate driving unit 305 or the detection unit driving unit 207d based on the information about the position of the edge of the substrate 110 acquired from the detection result of the first detection unit 802.

Accordingly, the edge of the substrate 110 can be easily brought into the detectable region of the second detection unit 207b, and it is possible to reduce the time required to bring the edge of the substrate 110 into the detectable region of the second detection unit 207b. Further, since the diameter of the substrate 110 is already known, the second detection unit 207b does not need to detect three or more points on the substrate 110 but only needs to detect at least two points. This is because, if there are the already known diameter of the substrate 110 and detection results of at least two points on the edge of the substrate 110, the position of the substrate 110 and the center position of the outer shape reference of the substrate 110 can be calculated. In step S106, the second detection unit 207b detects the mark formed on the substrate 110, and the upward sensor 315 detects the position of the member 109.

The processing in steps S101 to S104 (or S106) is a method for aligning the substrate 110. The control unit 111 stores a program for causing a computer to execute the alignment method.

Next, in step S107, the forming unit 103 performs forming processing for forming a film of the curable composition 201 on the substrate 110. In the forming processing, the control unit 111 aligns the member 109 and the substrate 110 based on the relative position of the reference mark arranged on the substrate stage 203 and the mark formed on the substrate 110 and the detection result of the position of the member 109 by the upward sensor 315. In the alignment, the difference (deviation amount) between the center position of the outer shape reference of the substrate 110 acquired from the detection result of the edge of the substrate 110 by the second detection unit 207b and the center position of the mark reference formed on the substrate 110 is reflected. The alignment of the member 109 and the substrate 110 may be performed based on the information about the position of the edge of the substrate 110 acquired from the detection result by the first detection unit 802. Then, the head 313 is driven to bring the member 109 into contact with the curable composition 201, and the curable composition 201 is cured by the illumination unit 307, so that the shape of the member 109 is transferred to the surface of the curable composition 201 and cured. Subsequently, the member 109 is separated from the curable composition 201.

In the adjustment of the relative position of the second detection unit and the substrate 110, it is desirable that the detection unit driving unit drives the second detection unit so that the position of the second detection unit with respect to the substrate 110 changes from a position on the center side of the substrate 110 toward a position on an outer periphery side of the substrate 110. By driving in this way, even in a case where the position of the edge of the substrate 110 changes toward the center of the substrate 110 due to the shrinkage of the substrate 110, the edge of the substrate 110 can be brought into the detectable region of the second detection unit in a short time.

According to the present exemplary embodiment, an example is described in which the second detection units 207a and 207b are arranged one each, but a plurality of the second detection units 207a and 207b may be arranged respectively. Further, according to the present exemplary embodiment, an example is described in which the measurement result of the substrate 110 by the first detection unit 802 in the pre-alignment unit 113 is applied to both the application unit 102 and the forming unit 103. However, the present disclosure is not limited to this example, and the measurement result may be applied to at least one of the application unit 102 and the forming unit 103.

There may be a case where a variation in outer diameter among a plurality of substrates 110 in a lot is expected to be small. In such a case, the position of the edge of the substrate 110 by the first detection unit 802 in the pre-alignment unit 113 may be detected with respect to a representative substrate in the lot (for example, a substrate to be processed first). Then, the information about the position of the edge of the substrate 110 acquired from the representative substrate in the lot may be applied to the other substrates 110 in the lot.

Further, in a case where a variation in the difference between the center position of the outer shape reference of the substrate 110 and the center position of the mark reference of the substrate 110 is small among the plurality of substrates 110 in the lot, the center position of the outer shape reference of the substrate 110 may be calculated only for the representative substrate in the lot. Then, the center position of the outer shape reference of the substrate 110 acquired from the representative substrate in the lot may be applied to the other substrates 110 in the lot.

According to the present exemplary embodiment, it is possible to shorten a time required to bring the edge of the substrate 110 into the detectable region of the second detection unit 207. Further, it is possible to reduce the number of times the second detection unit 207 detects the substrate 110.

A second exemplary embodiment is characterized in that, in addition to the features of the first exemplary embodiment, a difference between detection results of the first detection unit 802 and the second detection unit 207 is managed as an offset. For example, in a case where the first detection unit 802 and the second detection unit 207 use different detection methods, even if they each perform detection on the same substrate 110, detection results of the position of the edge of the substrate 110 (for example, the diameter of the substrate 110) may differ from each other.

Therefore, according to the present exemplary embodiment, the control unit (storage unit) 111 stores the difference between the detection results of the position of the edge of the substrate 110 (for example, the diameter of the substrate 110) by the first detection unit 802 and the second detection unit 207 as an offset value. Then, in a case where the second detection unit 207 detects the edge of the substrate 110, the control unit 111 controls driving of the substrate stage 203 (or the substrate stage 303) by applying the stored offset value. Accordingly, it is possible to further shorten the time required to bring the edge of the substrate 110 within the detectable region of the second detection unit 207. The offset value is not necessarily stored in the control unit 111 and may be stored in another storage unit.

The offset value may also be applied to calculation of the center position of the outer shape reference of the substrate 110 in the application unit 102 or the forming unit 103. In other words, the center position of the outer shape reference of the substrate 110 may be calculated based on the detection result of the position of the edge of the substrate 110 by the second detection unit 207 and a value obtained by applying the offset value (difference) to the detection result of the position of the edge of the substrate 110 by the first detection unit 802. Alternatively, the center position of the outer shape reference of the substrate 110 may be calculated based on the detection result of the position of the edge of the substrate 110 by the first detection unit 802 and a value obtained by applying the offset value (difference) to the detection result of the position of the edge of the substrate 110 by the second detection unit 207. In other words, the center position of the substrate 110 is calculated based on a value acquired by applying the offset value (difference) to one of the detection result of the position of the edge of the substrate 110 by the first detection unit 802 and the detection result of the position of the edge of the substrate 110 by the second detection unit 207, and the other detection result.

By calculating the center position of the outer diameter reference of the substrate 110 using the offset value in this way, it is possible to calculate the center position of the outer diameter reference of the substrate 110 by taking into account the difference in detection results between the detection units and to improve alignment accuracy of the substrate 110.

A third exemplary embodiment relates to a method for manufacturing an article characterized in that the article is manufactured using the above-described film forming apparatus 100.

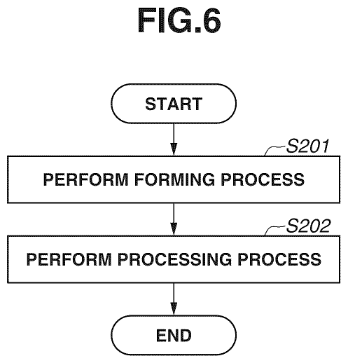

FIG. 6 is a flowchart illustrating the method for manufacturing an article according to the present exemplary embodiment. In step S201, a film of the curable composition 201 is formed on the substrate 110 using the above-described film forming apparatus 100 (forming process). Next, in step S202, a processing process is performed to process the substrate 110 on which the film of the curable composition 201 is formed.

Articles manufactured by the manufacturing method include, for example, a semiconductor integrated circuit (IC) element, a liquid crystal display element, a color filter, and a micro-electromechanical system (MEMS).

The processing process includes, for example, developing the substrate (photosensitive material) on which the film of the curable composition 201 is formed, etching and resist stripping on the developed substrate, dicing, bonding, and packaging. According to the present manufacturing method, it is possible to manufacture an article with a higher throughput compared to a conventional method.

The present disclosure is not limited to the above-described exemplary embodiments, and various modifications and changes can be made without departing from the spirit and the scope of the present disclosure. Therefore, the following claims are attached in order to publicize the scope of the present disclosure.

According to the present disclosure, a film forming apparatus that is advantageous in terms of throughput can be provided.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-125742, filed August 1, 2024, which is hereby incorporated by reference herein in its entirety.

What is claimed is:

1. A film forming apparatus that brings a curable composition on a substrate and a member into contact with each other to form a film of the curable composition, the film forming apparatus comprising:
a first unit including a first detection unit configured to detect an edge of the substrate;
a second unit including a second detection unit configured to detect an edge of the substrate and a driving unit configured to drive at least one of the substrate and the second detection unit;
a conveyance unit configured to convey the substrate from the first unit to the second unit; and
a control unit configured to control the driving unit,
wherein the control unit controls the driving unit based on information about a position of the edge of the substrate acquired from a detection result of the first detection unit.

2. The film forming apparatus according to claim 1, wherein the information about the position of the edge of the substrate includes at least one of information about a diameter of the substrate and information about a radius of the substrate.

3. The film forming apparatus according to claim 1, wherein the first detection unit detects three or more points on the edge of the substrate other than a notch portion formed on the substrate.

4. The film forming apparatus according to claim 3, wherein the second detection unit detects two or more points on the edge of the substrate other than the notch portion.

5. The film forming apparatus according to claim 1, wherein the driving unit performs driving so that a position of the second detection unit with respect to the substrate is changed from a position on a center side of the substrate to a position on an outer periphery side of the substrate.

6. The film forming apparatus according to claim 1,
wherein the second unit is a unit including a dispenser configured to supply the curable composition to the substrate, and
wherein the control unit adjusts a relative position of the dispenser and the substrate based on the information about the position of the edge of the substrate.

7. The film forming apparatus according to claim 1,
wherein the second unit is a unit including a dispenser configured to supply the curable composition to the substrate, and
wherein the control unit adjusts at least one of a supply position and a supply amount of the curable composition based on the information about the position of the edge of the substrate.

8. The film forming apparatus according to claim 1, wherein the control unit calculates a difference between a center position of the substrate obtained from a result of the second detection unit detecting a mark formed on the substrate and a center position of the substrate obtained from the information about the position of the edge of the substrate and a result of the second detection unit detecting the edge of the substrate.

9. The film forming apparatus according to claim 1, wherein a surface of the member that comes into contact with the substrate is flat.

10. The film forming apparatus according to claim 1, wherein the member has a pattern formed thereon that is to be transferred to the curable composition.

11. The film forming apparatus according to claim 1,
wherein the first unit is a pre-alignment unit configured to detect the edge of the substrate while rotating the substrate, and
wherein the pre-alignment unit adjusts a rotation angle of the substrate around an axis orthogonal to a surface of the substrate.

12. The film forming apparatus according to claim 1, wherein the second detection unit includes an imaging element, and a position of the edge of the substrate is detected based on an image captured by the imaging element.

13. The film forming apparatus according to claim 1, wherein the second detection unit is a sensor configured to measure a distance by irradiating a periphery of the edge of the substrate with light from above the substrate.

14. The film forming apparatus according to claim 1,
wherein the information about the position of the edge of the substrate is information about a specific substrate in a lot that includes a plurality of substrates, and
wherein the control unit applies the information about the position of the edge of the substrate of the specific substrate to substrates other than the specific substrate in the lot.

15. The film forming apparatus according to claim 1, further comprising a storage unit configured to store a difference between a detection result of the position of the edge of the substrate by the first detection unit and a detection result of the position of the edge of the substrate by the second detection unit,
wherein the control unit controls the driving unit based on the difference stored in the storage unit.

16. A film forming apparatus that brings a curable composition on a substrate and a member into contact with each other to form a film of the curable composition, the film forming apparatus comprising:
a first unit including a first detection unit configured to detect an edge of the substrate;
a second unit including a second detection unit configured to detect an edge of the substrate and a driving unit configured to drive at least one of the substrate and the second detection unit;
a conveyance unit configured to convey the substrate from the first unit to the second unit; and
a storage unit configured to store a difference between a detection result of a position of the edge of the substrate by the first detection unit and a detection result of a position of the edge of the substrate by the second detection unit.

17. The film forming apparatus according to claim 16, wherein a control unit calculates a center position of the substrate based on a value obtained by applying the difference to one of the detection result of the position of the edge of the substrate by the first detection unit and the detection result of the position of the edge of the substrate by the second detection unit, and the other detection result.

18. A method for alignment comprising:
detecting, in a first detection process, a position of an edge of a substrate by a first detection unit included in a first unit;
conveying, in a conveyance process, the substrate from the first unit to a second unit;
adjusting, in an adjustment process, a relative position of a second detection unit included in the second unit and the substrate based on information about the position of the edge of the substrate acquired from a detection result by the first detection unit; and
detecting, in a second detection process, a position of the edge of the substrate by the second detection unit.

19. A non-transitory computer-readable storage medium storing a program for causing a computer to execute the method for alignment according to claim 18.

20. A method for manufacturing an article, the method comprising:
forming, in a forming process, a film on a substrate using the film forming apparatus according to claim 1; and
processing, in a processing process, the substrate on which the film is formed by the forming process.
